(19) United States
(12) Patent Application Publication
(10) Pub. No.: US 2011/0262679 A1
(43) Pub. Date: Oct. 27, 2011

(54) GAS BARRIER FILM AND ORGANNIC DEVICE USING THE SAME

(75) Inventors: KAZUFUMI AZUMA, Kanagawa-Pref (JP); Satoko Ueno, Kanagawa-Pref (JP); Masayasu Suzuki, Kanagawa-Pref (JP); Yoshiyuki Konishi, Osaka-Pref (JP); Shinichiro Ishida, Osaka-Pref (JP)

(73) Assignee: SHIMADZU CORPORATION, Kyoto (JP)

(21) Appl. No.: 13/083,086

(22) Filed: Apr. 8, 2011

(30) Foreign Application Priority Data
Apr. 26, 2010 (JP) 2010-101056

(51) Int. Cl. B32B 3/02; C01B 21/068; C23C 16/513

(52) U.S. Cl. 428/68; 427/578; 423/344

(57) ABSTRACT

A SiNx film as a barrier film is provided. The film is formed at a low process temperature, has a high water vapor barrier performance and a high light transmittance, and is useful for sealing of a substrate formed by a flexible organic material, such as a plastic substrate. A barrier film is formed by silicon nitride (SiNx) having an atom ratio [N/(Si+N)] indicating a ratio of nitrogen N to silicon Si in the range of 0.60 to 0.65, by using a surface wave plasma chemical vapor deposition (CVD) device.

### CROSS-REFERENCE TO RELATED APPLICATION

This application claims the priority benefit of Japan patent application serial no. 2010-101056, filed on Apr. 26, 2010. The entirety of the above-mentioned patent application is hereby incorporated by reference herein and made a part of the specification.

### BACKGROUND OF THE INVENTION

1. Field of the Invention

The present invention generally relates to a gas barrier film having a high light transmittance and excellent gas barrier performance, and a gas barrier film useful for sealing of various image display devices, photovoltaic conversion devices, current control devices, and circuits using the devices, and a preparation method thereof.

2. Description of Related Art

In recent years, organic electronics are developed rapidly, as shown in various fields such as light emitting devices represented by organic electroluminescence (EL), organic thin film solar cells, or organic thin film transistors. The organic electronics formed with organic materials are used in combination with a plastic substrate, to fully exert the advantages of the organic materials, such as being light, impact resistant, and flexible according to the needs. Herein, the plastic substrate has a lower gas barrier performance than the glass substrate in the prior art, and fatal deterioration especially in contrast to the organic material. In the organic electronics using the plastic substrate, a plastic substrate having a film having a higher barrier performance formed thereon is needed.

In a liquid crystal display (LCD) device, the requirements for the flexible substrate are also improved, and a lighter flexible plastic substrate having a higher impact resistance tends to replace the glass substrate, to server as a substrate. However, compared with the glass substrate, the water or oxygen permeability of the plastic substrate is very high, and thus a problem of deterioration in display performance caused by exterior impurities entered into the liquid crystal exists. In view of the problem, researches on a plastic substrate having barrier films for obstructing water or oxygen formed on both surfaces thereof are performed. Due to the low thermal resistance of the plastic substrate, the barrier film must be formed at a low temperature, and a SiO₂ film is generally formed by sputtering in the prior art (see, for example, Patent Reference 1). However, the barrier performance required for a reliability of a level of a glass substrate cannot be obtained at present.

Moreover, as the next generation technology of LCD devices, the organic EL display devices attract more attentions. In the organic EL display devices, oxidation on an organic layer or on an electrode interface in contact with the organic layer will cause severe deterioration in display performance, and as for water vapor permeability, an extremely high level of barrier performance of 10⁻⁵ g/m²/day is required. In addition, as the glass transition temperature of the organic layer used is equal to or lower than 100, ° C., a film capable of being formed at a low temperature and having a high barrier performance is expected. In view of these demands, a barrier film is proposed which can be formed at a low temperature and has a structure with alternatively laminated inorganic layers and organic layers, as described in, for example, Patent References 2 and 3. However, such a laminated film is fabricated through a complicated process, and thus a problem concerning production cost occurs.

Moreover, in light emitting devices such as LCD devices or organic EL display devices, and circuits including the devices, the light transmittance of the barrier film must be high. For example, in the organic EL display devices, and especially in top-emission type organic EL display devices, if a light plastic film is used for sealing, a barrier film with high light transmittance is necessary. It is known that the SiNx film formed through plasma chemical vapor deposition (CVD) is compact and has low water vapor permeability, but has a disadvantage concerning light transmittance, as it is easily colored. Therefore, the SiNx film, as a barrier film, has not been used at a view side of the display devices.

### REFERENCE IN PRIOR ART

### Patent Reference

[Patent Reference 1] Japanese Patent Publication No. 1999-256338
[Patent Reference 2] Japanese Patent Publication No. 200887163
[Patent Reference 3] Japanese Patent Publication No. 2003-17244

The SiNx film formed through plasma CVD in the prior art has a disadvantage concerning light transmittance, as it is easily colored, thus having not been used as a barrier film in, for example, LCD devices or organic EL devices.

### SUMMARY OF THE INVENTION

(1) In a first technical solution, the present invention provides a barrier film including silicon nitride, where an atom ratio [N/(Si+N)] indicating a ratio of nitrogen N to silicon Si is in the range of 0.60 to 0.65.

(2) In a second technical solution, the present invention provides the barrier film according to the first technical solution, where silicon nitride is formed by using a surface wave plasma CVD apparatus, and the surface wave plasma CVD apparatus includes a dielectric window, for introducing microwave; a discharging gas outlet, for emitting a discharging gas; a film formation gas outlet, for emitting a film formation gas; a stage, for mounting a substrate; and a variable means, for changing a distance between the stage and surface wave plasma formed near the dielectric window with the discharging gas emitted from the discharging gas outlet. Silicon nitride is formed on the substrate mounted on the stage by reacting a SiH₄ gas and a NH₃ gas emitted from the film formation gas outlet with free radicals formed with the surface wave plasma.

(3) In a third technical solution, the present invention provides the barrier film according to the second technical solution, where the distance between the stage and the surface wave plasma is adjusted by using the variable means, to form the barrier film in a state that the temperature of the substrate mounted on the stage is equal to or lower than 200° C.

(4) In a fourth technical solution, the present invention provides a transparent substrate sealed with a barrier film, where the barrier film is a barrier film according to any one of the first to third technical solutions.

(5) In a fifth technical solution, the present invention provides a transparent substrate sealed with the barrier film according to the fourth technical solution, wherein the transparent substrate is a plastic substrate.

(6) In a sixth technical solution, the present invention provides a film for sealing a flexible device, having the barrier film according to any one of the first to the third technical solutions formed on a surface thereof.

(7) In a seventh technical solution, the present invention provides a flexible semiconductor device, sealed by the barrier film according to any one of the first to the third technical solutions.

(8) In an eighth technical solution, the present invention provides the flexible semiconductor device according to the seventh technical solution, including any one of an organic semiconductor-containing light emitting device, an organic semiconductor-containing photovoltaic conversion device, an organic semiconductor-containing current control device, or an organic electroluminescent (EL) device.

(9) In a ninth technical solution, the present invention provides a method for forming the barrier film according to the second or the third technical solution, where a flow rate ratio of SiH₄ gas to NH₃ gas is adjusted to form the barrier film formed by silicon nitride by using a surface wave plasma chemical vapor deposition (CVD) device.

### EFFECTS OF THE INVENTION

According to the present invention, a SiNx film, as a gas barrier film having a high water vapor barrier performance and a light transmittance, can be formed at a low temperature.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic vertical cross-sectional view of a plasma CVD apparatus used in the present invention.

FIG. 2 is a graph showing a relation between a ratio of a silane (SiH₄) gas to an ammonia (NH₃) gas in plasma for generating a barrier film, and a proportion of nitrogen in the barrier film formed by SiNx by using the plasma.

FIG. 3 is a graph showing a relation between a proportion of nitrogen in a barrier film and a water vapor permeability of the barrier film, and a relation between the proportion of nitrogen in the barrier film and the light transmittance of the barrier film.

FIG. 4 is a schematic cross-sectional view of a top-emission type organic EL device using a barrier film of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

<Description of Apparatus>

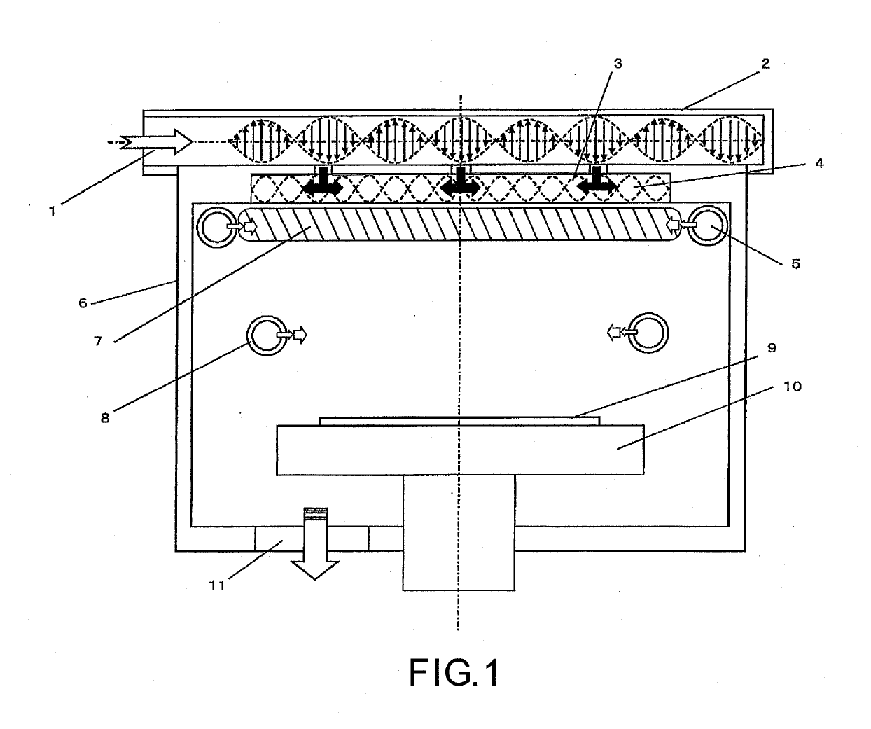

Hereinafter, a surface wave plasma apparatus used in the present invention is briefly described with reference to FIG. 1. In addition, the surface wave plasma CVD apparatus used for forming the barrier film of the present invention is a film formation device well known in the art (see, for example, Japanese Patent Publication No. 2006-286892).

In the surface wave plasma CVD apparatus used in the present invention, a microwave 1 transmits through a microwave wave guide 2, and reaches a dielectric window 4 via a slot antenna 3. The microwave 1 is introduced into a reaction chamber 6 through the dielectric window, and becomes a surface wave transmitting along a surface of the dielectric window.

An Argon (Ar) gas is emitted from a discharging gas outlet 5 into the reaction chamber 6, and excited with the surface wave transmitted along the surface of the dielectric window, so as to form plasma 7 near the surface of the dielectric window. The plasma 7 contains free radicals of Ar, which diffuse from the surface wave plasma formed near the dielectric window into reaction chamber 6.

A film formation gas formed by silicane (SiH₄) and ammonia (NH₃) is emitted from a film formation gas outlet 8 disposed between the discharging gas outlet 5 and a substrate (or a sealing material such as a plastic film) 9 for forming the film, and the film formation gas is decomposed with free radicals of Ar, to generate and deposit SiNx onto the substrate 9, so as to form a SiNx film. The substrate 9 is mounted on a stage 10, which is optionally heated with a heater (not shown in Figures). The reaction chamber 6 is evacuated through an exhaust hole 11 by an exterior vacuum pump, or the pressure in the reaction chamber is controlled by the supplying rates of the discharging gas and the film formation gas, and the exhaust of the vacuum pump in generation of the plasma.

Moreover, a distance between the stage 10 and the surface wave plasma formed near the dielectric window is dependent on the temperature condition of the material of the substrate 9 mounted on the stage 10. The substrate 9 will not easily be influenced by the heat of the surface wave plasma with the increasing of the distance, and thus the temperature of the substrate 9 becomes lower. The distance is changed by adjusting the position of the stage in a height direction of the reaction chamber 6 by using a lifting device not shown in figures.

<Formation of Barrier Film>

Herein, a method for forming the silicon nitride film of the present invention is described.

In the present invention, in formation of the barrier film formed by SiNx, a surface wave plasma CVD apparatus is used. In the surface wave plasma CVD apparatus, SiNx is formed by reacting a silicane (SiH₄) gas and ammonia (NH₃) gas as materials of SiNx with free radicals formed by the surface wave plasma in a site far away from the surface wave plasma. As such, the barrier film formed by SiNx is formed on a substrate disposed in the site far away from the surface plasma-generating region, such that the barrier film of SiNx can be formed on the substrate at a low temperature.

In the present invention, the position of the stage can be adjusted with the lifting device, such that the temperature of the substrate mounted on the stage is equal to or lower than 200° C., so as to form the barrier film of SiNx.

However, as described below, the main objective of the present invention is to generate SiNx having a specific composition at a temperature equal to or lower than 200° C., and thus a device other than the surface wave plasma apparatus may be used, as long as SiNx can be formed at a low temperature.

Moreover, the barrier film of the present invention is characterized by having the features of the present invention kept even if SiNx is formed at a high temperature, and thus a device other than the surface wave plasma apparatus may be used to generate the barrier film, without the necessary limitation of generating SiNx at a low temperature.

In a silicon nitride film formed through thermal CVD, the content of hydrogen and oxygen in the film is very low. In formation of an amorphous silicon nitride film, the film structure is determined by the reaction of the raw material gases near the surface, such that when the surface temperature of the substrate is high, sufficient energy required to move the precursors (SiHx and NHx formed by SiH₄ and NH₃) of the silicon nitride film from the surface to a stable site is imparted, and thus a compact film is formed. Meanwhile, due to the high surface temperature of the substrate, Si—H and N—H bonds are easily broken, and thus a film containing less hydrogen therein is formed. Furthermore, when the surface temperature is high, the adhesion coefficient to the surface of the film is low, and thus the amount of oxygen entered into the film is low.

In contrast, in a film formed at a low temperature equal to or lower than 200° C., as the surface temperature is low, sufficient energy for motion cannot be imparted on the surface in the formation of the film, and thus the formed film easily has a unstable film structure that is easier to be oxidized. Due to the low substrate temperature, large amount of Si—H and N—H bonds are remained in the film, and the content of hydrogen present in the film is about ten percentage or higher.

When the silicon nitride film is formed with the SiH₄ gas and the NH₃ gas as materials at a temperature equal to or lower than 200° C., if the flow rate of the NH₃ gas is low with respect to the flow rate of the SiH₄ gas, the film will has a structure in which x in SiNx is small. In a film with surplus Si, as Si has more dangling bond exist, after formation of the film, Si is oxidized, and the oxygen content in the film is increased. In addition, if the flow rate of the NH₃ gas is high with respect to the flow rate of the SiH₄ gas, the film will have a constitution in which x in SiNx is large. In this case, the film has more Si—(NH₂) bonds, and Si—O bond is easily formed in view of the replacement of the NH₂ group by an oxygen atom. It is known that the oxygen content in the SiNx film correlates with the barrier performance, and the higher the oxygen content is, the lower the barrier performance of the film is. In the present invention, the correlation is confirmed hereinafter.

By using the surface wave plasma CVD apparatus, the flow rate of the Ar gas is set at 350 sccm, and the flow rate ratio of the SiH₄ gas to the NH₃ gas is changed, so as to form SiNx films having various compositions on the Si substrate. The formed film is about 200 nm thick. Moreover, in formation of the film with these gases, the pressure is adjusted to 10 Pa. The stage is not heated. The distance between the dielectric window and the stage is 200 mm, and the output density of the microwave is 1.57 W/cm². Under these conditions, if the stage is not heated, the surface temperature of the substrate mounted on the stage will rise till be thermostabilized at 50° C.

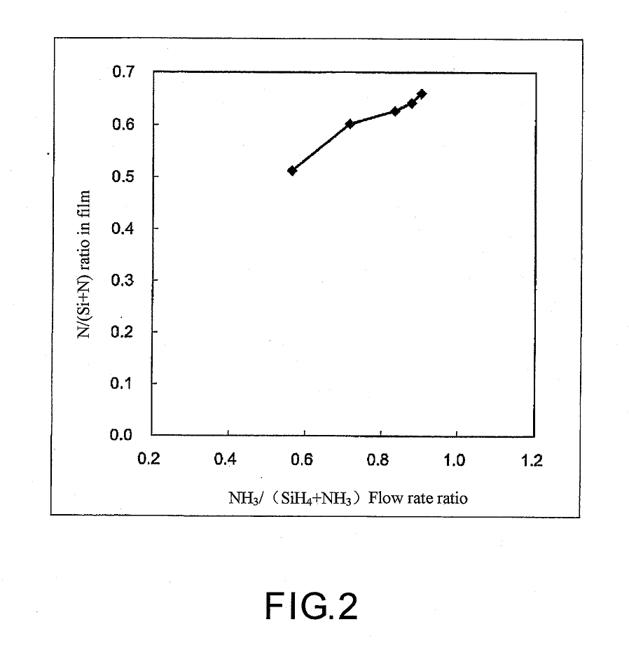

FIG. 2 shows composition ratios (N/(Si+N), the longitudinal axis) of SiNx film formed when the flow rate ratio (NH₃/(SiH₄+NH₃), the horizontal axis) of the film formation gas is changed. In addition, when the composition ratio of SiNx film reaches 0.65, the flow rate ratio of the film formation gas is 0.88, which is obtained with the NH₃ gas of 500 sccm and the SiH₄ gas of 70 sccm.

Moreover, the composition ratio of Si to N is determined by Rutherford back scattering (RBS).

Next, the performances of the SiNx films having various compositions and formed on the Si substrate are determined.

Table 1 shows results obtained by placing the formed SiNx films having various composition ratios in a clean room in the atmosphere for 3 days, and then determining the oxygen contents in the SiNx films by RBS. In the determination by RBS, the energy of the ion beam for determination is adjusted, such that a SiNx film of 200 nm will not be penetrated. Accordingly, in the determination, no influence from the Si substrate exists.

TABLE 1
Composition ratio and oxygen content in the SiNx film

| N/(Si + N) ratio | Oxygen content in the film (/cm³) |
|---|---|
| 0.22 | 1 × 10²² |
| 0.51 | 5 × 10²¹ |
| 0.57 | 3 × 10²⁰ |
| 0.60 | 2 × 10¹⁹ |
| 0.65 | 3 × 10¹⁹ |
| 0.67 | 1 × 10²⁰ |
| 0.70 | 6 × 10²⁰ |

It can be known from the results in Table 1 that when the composition ratio N/(Si+N) of the SiNx film is in the range of 0.60 to 0.65, the oxygen content in the film is the lowest. That is, the flow rate ratio of the film formation gas is adjusted for forming the film in a manner such that the composition ratio N/(Si+N) in the SiNx film is in the range of 0.60 to 0.65, so as to obtain a SiNx film having a low oxygen content and high barrier performance.

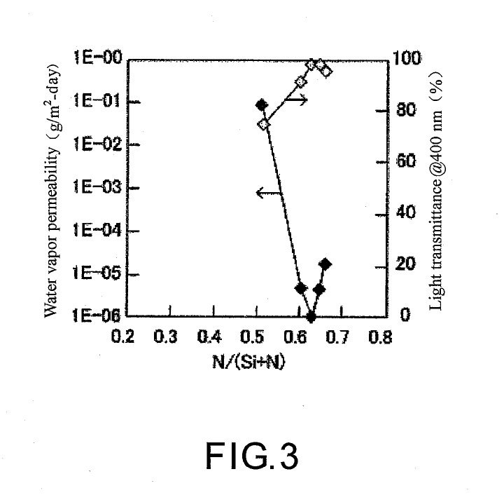

FIG. 3 shows results of water vapor permeability of the SiNx films having various compositions determined by the calcium corrosion method, with black squares and lines connecting the squares. Furthermore, in the determination by the calcium corrosion method, a SiNx film having the same composition is formed on a polyimide film.

According to Table 1, in the SiNx film having a N/(Si+N) ratio of 0.65, the oxygen content is 3×10¹⁹/cm³, and the water vapor permeability is 5×10⁻⁶ g/m²-day as shown in FIG. 3, and the SiNx film is confirmed to have good barrier performance. This indicates that the composition of the SiNx film may be set at about Si₃N₅. In addition, the composition of the SiNx film having a N/(Si+N) ratio of 0.51 is close to Si₃N₃, according to Table 1, the oxygen content in the SiNx film having such a composition is 5×10²¹/cm³, that is, above 100 times higher than that of the SiNx film having a N/(Si+N) ratio of 0.65, and the water vapor permeability is 0.1 g/m²-day, which is increased by above 10000 times, and thus the barrier performance is significantly deteriorated, compared with the SiNx film having a N/(Si+N) ratio of 0.65.

Accordingly, the oxygen content in the SiNx film strongly correlates to the water vapor permeability, and it is confirmed that good water vapor barrier performance is exhibited when the composition ratio N/(Si+N) of the SiNx film is in the range of 0.60 to 0.65.

Then, the light transmittance of the films having the compositions is determined at a wavelength of 400 nm.

FIG. 3 shows determination results of the light transmittance of the SiNx films having various compositions with white squares and lines connecting the squares. In the film having a low nitrogen ratio (N/(Si+N)=0.51), the light transmittance is about 75% when the film thickness is 200 nm; and a transmittance of 98% can be obtained when the N/(Si+N) ratio is in the range of 0.60 to 0.65.

It can be clearly known from the determination results of the light transmittance as shown in FIG. 3 that, the light transmittance also strongly correlates with the oxygen content and the water vapor permeability of the film, and good performance values of the light transmittance and the water vapor permeability are exhibited when the N/(Si+N) ratio is in the range of 0.60 to 0.65.

<Fabrication of Organic EL Display Device>

Hereinafter, a top-emission type organic EL device is fabricated by using the film having good barrier performance as a film sealer of an organic EL display device.

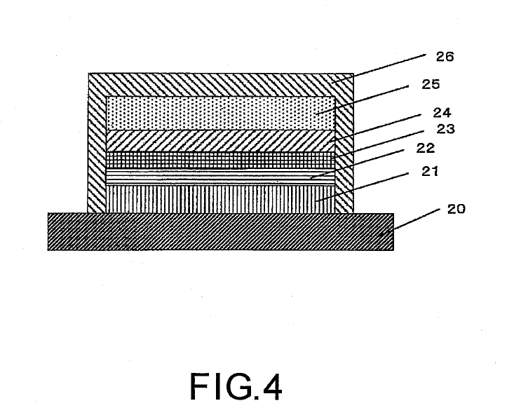

As shown in FIG. 4, the top-emission type organic EL device is provided, and first, a film of aluminum (Al) as a reflective metal is formed on a glass substrate 20 by evaporation. Then, Al is patterned by photolithography, to form a reflective electrode 21. Next, a hole transport layer 22 and a light emitting layer 23 are formed on the reflective electrode by printing. The hole transport layer is used for transporting the holes injected from the electrode to the light emitting layer, in which a mixture of a polythiophene-based compound and polystyrene sulphonic acid is used. The light emitting layer 23 is a recombination region of electrons and holes respectively injected from the reflective electrode 21 and a transparent electrode 25 when a voltage is applied. The light emitting layer is formed by a material with high luminescence efficiency. Specifically, a polyphenylenevinylene-based compound is used. An electron transport layer 24 is a layer for transporting electrons injected to the light emitting layer, in which a quinolinol complex doped with an alkaline earth metal aluminum is used. The transparent electrode 25 is laminated on the electron transport layer 24 by spluttering. In order to seal the organic EL device thus formed, a barrier film 26 is formed and covers the whole device. The barrier film is formed to a thickness of 500 nm through the surface wave plasma CVD, by introducing the argon gas as a discharging gas, and a mixed gas of the silicane gas and the ammonia gas as a film formation gases into a film forming chamber, and using the method as described in formation of barrier film.

The organic EL device thus obtained is placed in a tank with a constant temperature of 60° C. and a constant humidity of 90% RH (RH=relative humidity), and observed for a light emitting surface under an optical microscope. The ratio of the initial dark spot area and the dark spot area after 1500-hour placement is 5%.

As a comparative example, the organic EL display device is fabricated with a film having a film forming condition of composition Si₃N₄ (that is, N/(Si+N) ratio is 0.57) as a sealing film, and placed into a tank with a constant temperature of 60° C. and a constant humidity of 90% RH, and observed for a light emitting surface under an optical microscope. By using the same method, it is found that the ratio of the initial dark spot area and the dark spot area after 1500-hour placement is 58%. It can be known that in the SiNx film formed at such a low temperature, the N/(Si+N) ratio is in the range of 0.60 to 0.65, the device will not easily deteriorate, and thus the serving life is prolonged.

<Fabrication of Flexible Liquid Crystal Display Device>

At both surfaces of a polyethersulphone film with a thickness of 100 microns, a barrier film having a composition ratio of Si₃N_{5.1} is formed to a thickness of 500 nm by using the method as described in formation of the barrier film. Then, an ITO film is formed at a single surface of the film by spluttering. Next, a polyamide film capable of being imidized is coated by spin coating in a low-temperature process at 150° C., and dried, so as to form an oriented film. The oriented film is rubbed in a rubbing direction specified such that a twist angle after fabrication of the liquid crystal cell is 240 degrees. Dispersion with silica spacer having a diameter of 5 microns dispersed in ethanol is coated by spin coating, and dried. Then, a sealing agent is printed on a single substrate by screen printing, and an upper substrate and a lower substrate are attached and hardened by heating. Afterwards, the liquid crystal cells are placed in a vacuum device for injecting liquid crystals, and injected under vacuum.

The flexible LCD device thus obtained is placed in an environment of 60° C. and 90% RH for 500 hours, and then the voltage holding rate of the liquid crystal cells is determined. The result shows that the voltage holding rate is 98% with respect to the initial value. For comparison, a liquid crystal device is fabricated with a glass substrate by using the same process as above, and placed in an environment of 60° C. and 90% RH for 500 hours, and then the voltage holding rate of the liquid crystal cells is determined. The result shows that the voltage holding rate is 99%.

Moreover, a liquid crystal device is fabricated with a substrate having films formed to a thickness of 500 nm as barrier films with the structure of the barrier film respectively on both surfaces of the polyethersulphone film as a substrate, under a condition for forming a film having a composition of Si₃N₄ at a film forming temperature of 50° C., and placed in an environment of 60° C. and 90% RH for 500 hours, and then the voltage holding rate of the liquid crystal cells is determined. The result shows that the voltage holding rate is 86%. That is, it can be known that, the barrier formed to have a composition ratio of Si₃N_{5.1} has good performance as a barrier film of a plastic substrate, as the water vapor barrier performance is substantially at the same level as that of the glass substrate.

As such, the SiNx film of the present invention is formed at a surface of plastic substrate at a low temperature, thus having a water vapor barrier performance similar to that of the glass substrate. Therefore, a plastic substrate used in an organic thin film transistor or an organic thin film solar cell requiring a low-temperature process has the SiNx film of the present invention formed thereon as a barrier film, and it is confirmed that good barrier performance at the same level as that obtained with the glass substrate can be obtained in any case.

As described above, the barrier film of the present invention can be used as a barrier film for a plastic substrate used in various light emitting devices, photovoltaic conversion devices, and current control devices, and is most useful as a transparent barrier film.

In recent years, the light emitting device such as an organic EL device and the photovoltaic conversion device such as a solar cell are gradually developed to have a flexible configuration, and the barrier film of the present invention is very useful as a sealing means in the flexible devices.

Moreover, as the barrier film of the present invention can be formed at a low temperature, the barrier film of the present invention is very useful as a barrier film in various light emitting devices, photovoltaic conversion devices, current control devices, and biomedical microelectromechanical systems (BioMEMS) devices, and organic EL devices, and especially in organic semiconductor-containing organic semiconductor devices.

Thereby, the barrier film of the present invention can be formed on various plastic films, to server as a flexible film for sealing. Herein, the barrier film of the present invention is also very useful in case that the sealing film requires to be transparent.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A barrier film, comprising silicon nitride, wherein an atom ratio [N/(Si+N)] indicating a ratio of nitrogen N to silicon Si is in the range of 0.60 to 0.65.

2. The barrier film according to claim 1, wherein
the silicon nitride is formed by using a surface wave plasma chemical vapor deposition (CVD) device; and
the surface wave plasma CVD apparatus comprises:
a dielectric window, for introducing microwave;
a discharging gas outlet, for emitting a discharging gas;
a film formation gas outlet, for emitting a film formation gas;
a stage, for mounting a substrate; and
a variable means, for changing a distance between the stage and surface wave plasma formed near the dielectric window with the discharging gas emitted from the discharging gas outlet; and
the silicon nitride is formed on the substrate mounted on the stage by reacting a Sin₄ gas and a NH₃ gas emitted from the film formation gas outlet with free radicals formed with the surface wave plasma.

3. The barrier film according to claim 2, wherein:
the distance between the stage and the surface wave plasma is adjusted by using the variable means, to form the barrier film in a state that the temperature of the substrate mounted on the stage is equal to or lower than 200° C.

4. A transparent substrate sealed with a barrier film, wherein the barrier film is a barrier film according to claim 1.

5. A transparent substrate sealed with a barrier film, wherein the barrier film is a barrier film according to claim 2.

6. A transparent substrate sealed with a barrier film, wherein the barrier film is a barrier film according to claim 3.

7. The transparent substrate sealed with a barrier film according to claim 4, wherein the transparent substrate is a plastic substrate.

8. The transparent substrate sealed with a barrier film according to claim 5, wherein the transparent substrate is a plastic substrate.

9. The transparent substrate sealed with a barrier film according to claim 6, wherein the transparent substrate is a plastic substrate.

10. A film for sealing a flexible device, comprising a barrier film according to claim 1 formed on a surface thereof.

11. A film for sealing a flexible device, comprising a barrier film according to claim 2 formed on a surface thereof.

12. A film for sealing a flexible device, comprising a barrier film according to claim 3 formed on a surface thereof.

13. A flexible semiconductor device, sealed by a barrier film according to claim 1.

14. A flexible semiconductor device, sealed by a barrier film according to claim 2.

15. A flexible semiconductor device, sealed by a barrier film according to claim 3.

16. The flexible semiconductor device according to claim 13, wherein
the flexible semiconductor device is any one of an organic semiconductor-containing light emitting device, an organic semiconductor-containing photovoltaic conversion device, an organic semiconductor-containing current control device, or an organic electroluminescent (EL) device.

17. The flexible semiconductor device according to claim 14, wherein
the flexible semiconductor device is any one of an organic semiconductor-containing light emitting device, an organic semiconductor-containing photovoltaic conversion device, an organic semiconductor-containing current control device, or an organic electroluminescent (EL) device.

18. The flexible semiconductor device according to claim 15, wherein
the flexible semiconductor device is any one of an organic semiconductor-containing light emitting device, an organic semiconductor-containing photovoltaic conversion device, an organic semiconductor-containing current control device, or an organic electroluminescent (EL) device.

19. A method for forming a barrier film according to claim 2, wherein
a flow rate ratio of a SiH₄ gas to a NH₃ gas is adjusted to form the barrier film comprising silicon nitride by using a surface wave plasma chemical vapor deposition (CVD) apparatus.

20. A method for forming a barrier film according to claim 3, wherein
a flow rate ratio of a SiH₄ gas to a NH₃ gas is adjusted to form the barrier film comprising silicon nitride by using a surface wave plasma chemical vapor deposition (CVD) apparatus.
